(19) United States
(12) Patent Application Publication
(10) Pub. No.: US 2026/0059778 A1
(43) Pub. Date: Feb. 26, 2026

(54) SEMICONDUCTOR DEVICE

(71) Applicant: FUJI ELECTRIC CO., LTD., Kawasaki-shi (JP)

(72) Inventor: Misaki HIROHATA, Matsumoto-city (JP)

(73) Assignee: FUJI ELECTRIC CO., LTD., Kawasaki-shi (JP)

(21) Appl. No.: 19/375,919

(22) Filed: Oct. 31, 2025

Related U.S. Application Data
(63) Continuation of application No. PCT/JP2024/032438, filed on Sep. 10, 2024.

(30) Foreign Application Priority Data
Nov. 7, 2023 (JP) 2023-190157

(51) Int. Cl. H10D 12/00; H10D 8/00; H10D 62/10; H10D 64/00

(52) U.S. Cl. CPC H10D 12/415; H10D 8/422; H10D 12/481; H10D 62/107; H10D 64/111

(57) ABSTRACT

The semiconductor device includes: an active portion, a termination region that surrounds the active portion in a plan view, a drift layer of a first conductivity type that is provided over the active portion and the termination region, a base region of a second conductivity type that is provided on an upper surface side of the drift layer at the active portion, and a well region of the second conductivity type that is provided on the upper surface side of the drift layer at the termination region and that surrounds the base region in the plan view, in which the well region has a recess portion on a lower side, and a dimension of the recess portion in a depth direction is ⅓ or more and ⅔ or less of a dimension of the well region in the depth direction.

### CROSS-REFERENCE TO RELATED APPLICATION

This application is a Continuation of PCT Application No. PCT/JP2024/032438, filed on Sep. 10, 2024, and claims the priority of Japanese Patent Application No. 2023-190157, filed on Nov. 7, 2023, the content of which are incorporated herein by reference.

### BACKGROUND OF THE INVENTION

### Technical Field

The present disclosure relates to a semiconductor device, and particularly to a high-breakdown voltage semiconductor device.

### Background Art

A high-breakdown voltage semiconductor device such as a power MOSFET or a power IGBT has a breakdown voltage withstanding structure in a termination region surrounding an active portion to secure a breakdown voltage. There are various types of breakdown voltage withstanding structures. For example, as described in JP 2003-197898 A and JP 2009-38356 A, there are a field plate structure, a guard ring structure, a RESURF structure, and the like.

JP 3444081 B describes a diode in which a retreat length of an anode electrode in a region in which a p+ conductivity type semiconductor layer and the anode electrode are not in contact with each other is longer than a diffusion length of a hole in an n-conductivity type semiconductor layer.

In the termination region, an electric field is likely to be concentrated on an outer-side end portion of a p-type region. Therefore, there is a concern that breakdown voltage performance of the semiconductor device deteriorates.

### SUMMARY OF THE INVENTION

In view of the problems described above, an object of the present disclosure is to provide a semiconductor device in which a decrease in breakdown voltage performance is suppressed.

In order to achieve the object described above, an aspect of the present disclosure, there is provided a semiconductor device including: (a) an active portion; (b) a termination region surrounding the active portion in a plan view; (c) a drift layer of a first conductivity type provided over the active portion and the termination region; (d) a first region of a second conductivity type provided on an upper surface side of the drift layer at the active portion; and (e) a second region of the second conductivity type provided on the upper surface side of the drift layer at the termination region and surrounding the first region in the plan view, in which (f) the second region has a recess portion on a lower side, and (g) a dimension of the recess portion in a depth direction is ⅓ or more and ⅔ or less of a dimension of the second region in the depth direction.

The semiconductor device may further include: a transistor provided at the active portion and having the first region as a base region; and a gate wiring electrode surrounding the active portion in the plan view and electrically connected to a gate electrode of the transistor, in which the second region may be a well region, and may have an upper surface facing the gate wiring electrode, and when an active portion side is defined as an inner side and a termination region side is defined as an outer side, the recess portion may be located on the outer side of an inner-side end portion of the gate wiring electrode.

In addition, the well region and the recess portion may be provided in an annular shape along the gate wiring electrode in the plan view.

In addition, the recess portion may be located on the outer side of an outer-side end portion of the gate wiring electrode.

In addition, along a direction toward the outer side, when a dimension from the inner-side end portion to the outer-side end portion of the gate wiring electrode is defined as W1 and a dimension from a position at which the inner-side end portion of the gate wiring electrode is present to a position at which the recess portion is present is defined as W2, a dimension of the well region in the depth direction is defined as d1, and a constant C is a value of 0.75 or more and 0.85 or less, a relationship of W2≥W1+C×d1 may be satisfied.

In addition, a field plate may be provided in a region on the outer side of the recess portion of the well region.

In addition, the recess portion may be located on the inner side of an outer-side end portion of the gate wiring electrode.

In addition, the well region may have a plurality of the recess portions on a lower side.

In addition, the well region may have a first recess portion located on the outer side of an outer-side end portion of the gate wiring electrode and a second recess portion located on the inner side of the outer-side end portion of the gate wiring electrode, as the recess portion.

In addition, a dimension of the second recess portion in the depth direction may be larger than a dimension of the first recess portion in the depth direction.

In addition, the semiconductor device may further include: a breakdown voltage structure of the second conductivity type provided on the upper surface side of the drift layer and located on the outer side of the well region.

In addition, the breakdown voltage structure may be a guard ring.

In addition, the well region may overlap with the entire gate wiring electrode in the plan view.

In addition, the semiconductor device may further include: a main electrode in contact with an upper surface of a main region of the transistor, in which the well region may be electrically connected to the main electrode.

In addition, the gate electrode of the transistor may be of a trench gate type.

In addition, the semiconductor device may further include: a diode having the first region as a main region, in which the second region may be an inactive region, and an inner-side end portion of the second region may be in contact with an outer-side end portion of the first region.

In addition, the semiconductor device may further include: a third region of the first conductivity type serving as a main region and provided on a lower surface side of the drift layer.

In addition, when an active portion side is defined as an inner side and a termination region side is defined as an outer side, an outer-side end portion of the third region may be located on the inner side of an outer-side end portion of the drift layer, and the recess portion may be located on the inner side of the outer-side end portion of the third region.

In addition, when an active portion side is defined as an inner side and a termination region side is defined as an outer side, an outer-side end portion of the third region may be located on the inner side of an outer-side end portion of the drift layer, and the recess portion may be located on the outer side of the outer-side end portion of the third region.

In addition, along a direction toward the outer side, when a dimension in a lateral direction from a position at which the outer-side end portion of the third region is present to a position at which the recess portion is present is defined as W4, the dimension of the second region in the depth direction is defined as d1, and a constant C is a value of 0.75 or more and 0.85 or less, a relationship of C×d1<W4<20 μm may be satisfied.

In addition, the semiconductor device may further include: a fourth region of the second conductivity type provided on an upper surface side of the third region, in which an outer-side end portion of the fourth region may be located on the inner side of an outer-side end portion of the second region, and the recess portion may be located on the inner side of the outer-side end portion of the fourth region.

In addition, the second region may have a plurality of the recess portions on a lower side.

In addition, the dimension of the second region in the depth direction may be provided to be the same as a dimension of the first region in the depth direction.

In addition, the recess portion may be provided in an annular shape along the second region in the plan view.

The above outline of the invention does not list all the necessary features of the present invention. In addition, a sub-combination of these feature groups may also be an invention.

### BRIEF DESCRIPTION OF THE DRAWINGS

FIG. 1 is a plan view illustrating a planar configuration of a semiconductor device according to a first embodiment and a position at which a gate wiring electrode is disposed;

FIG. 2 is a schematic cross-sectional view illustrating a longitudinal cross-sectional configuration when a cross section is viewed along A-A section line in

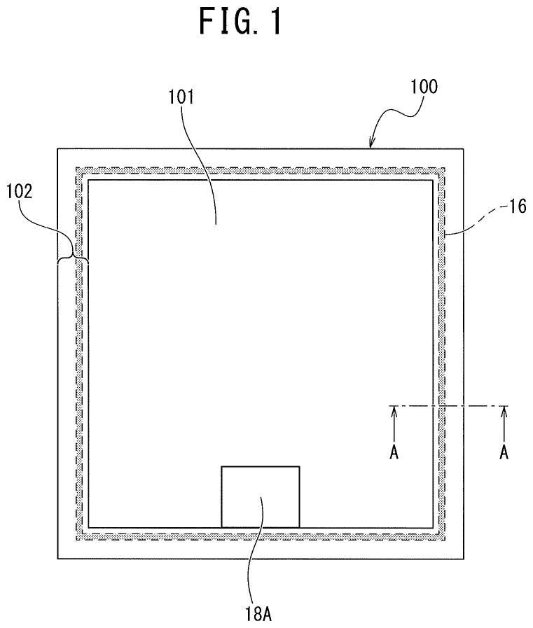

FIG. 1;

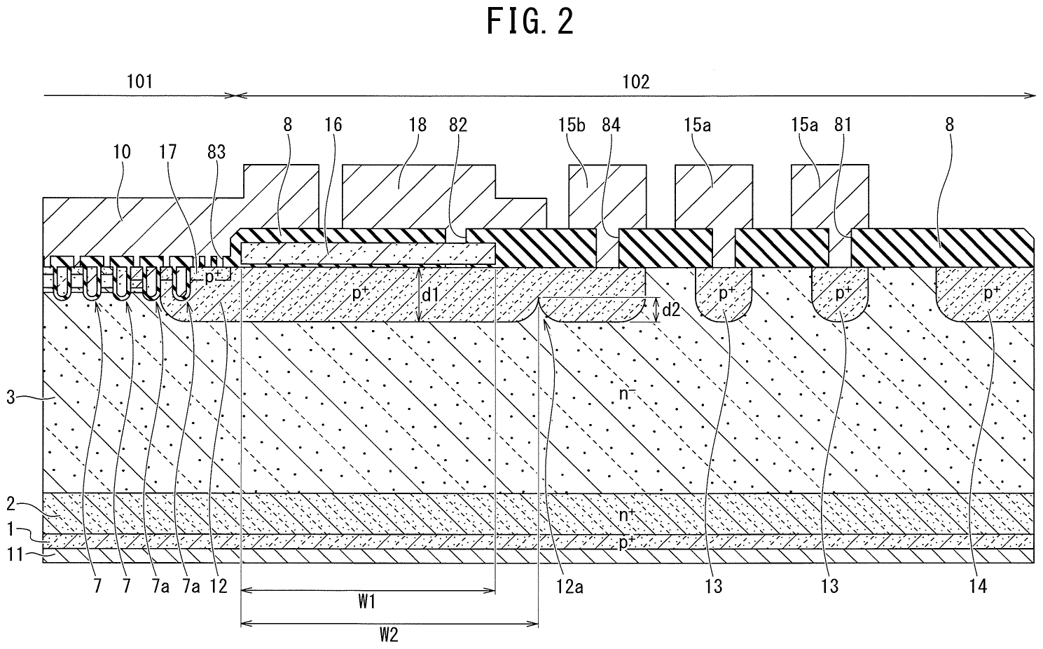

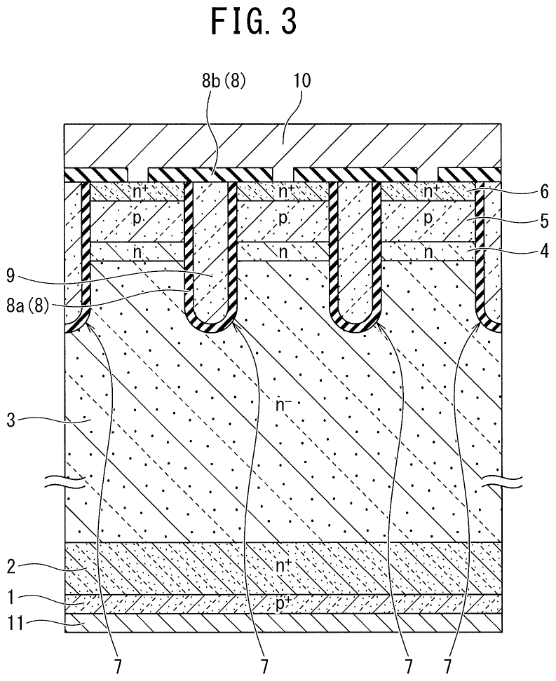

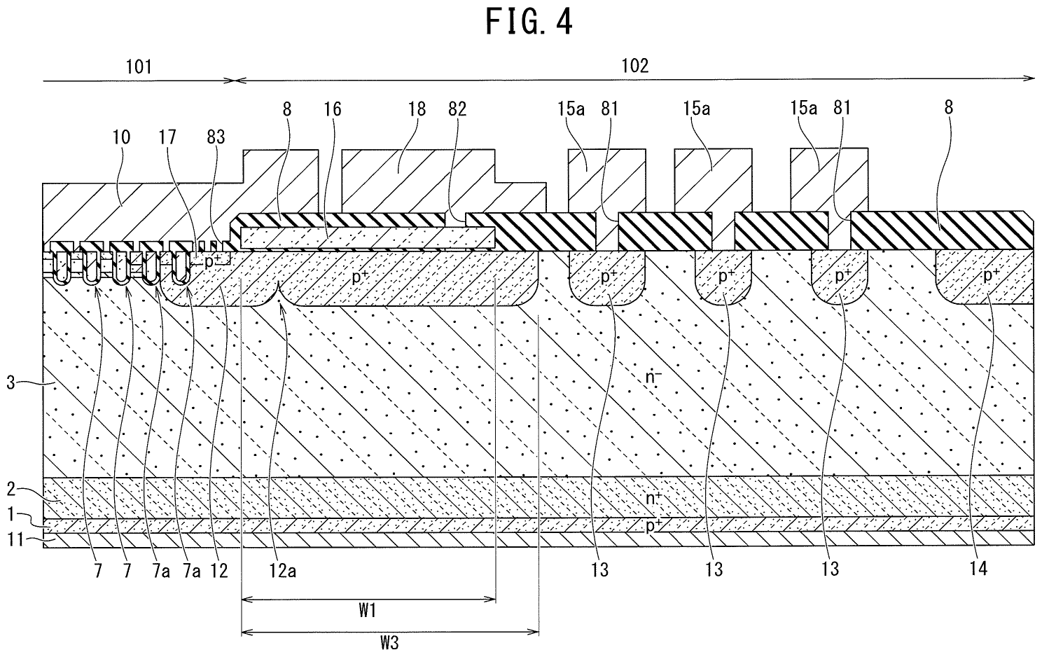

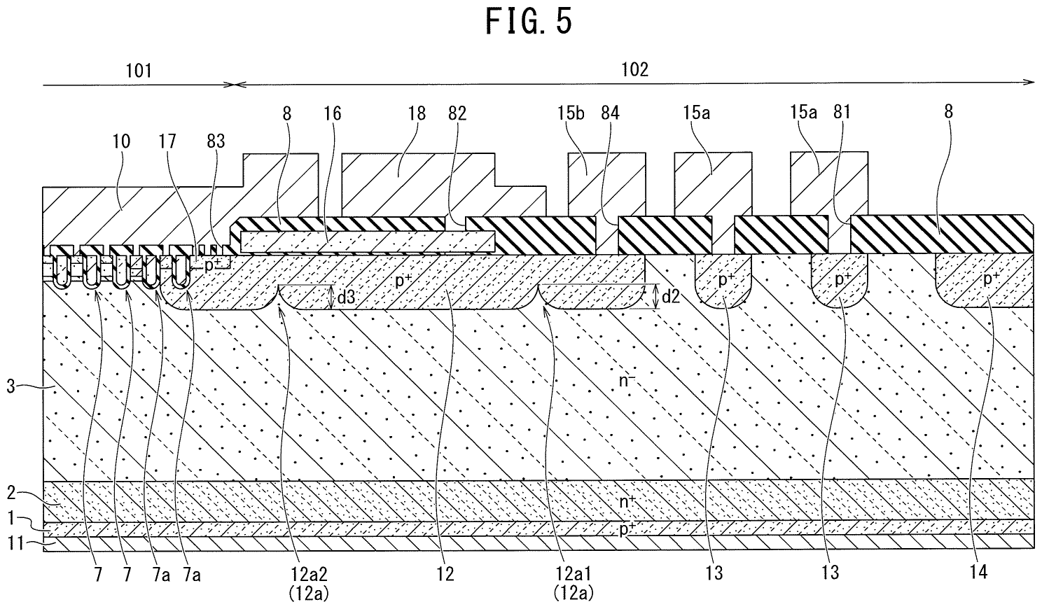

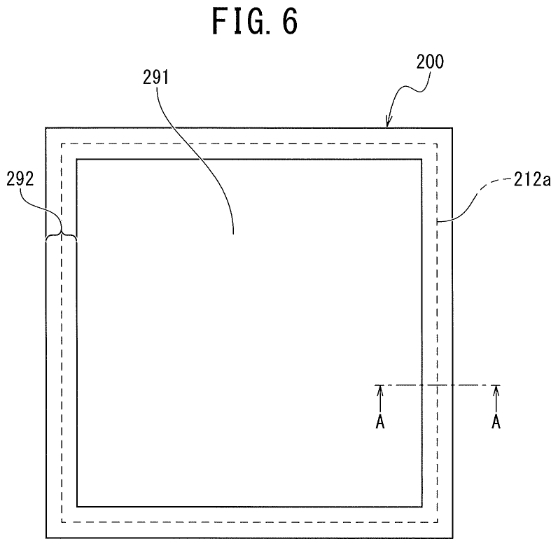

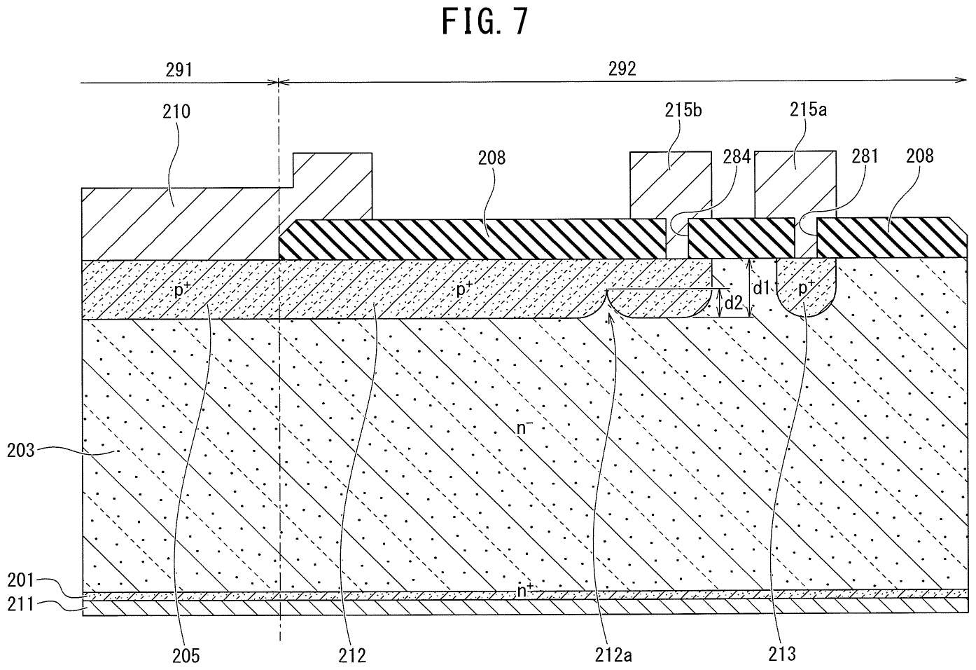

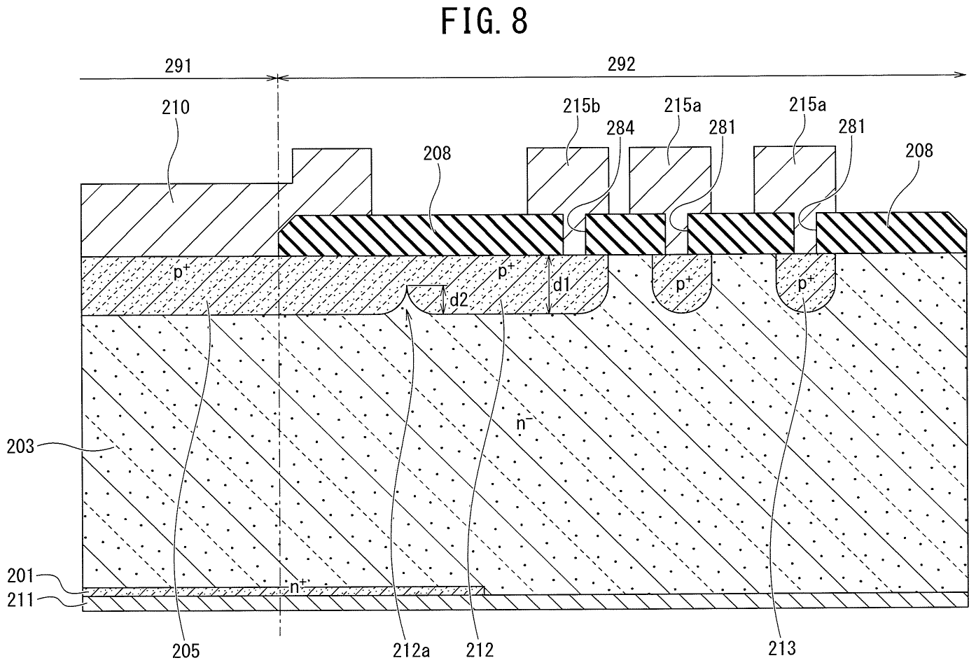

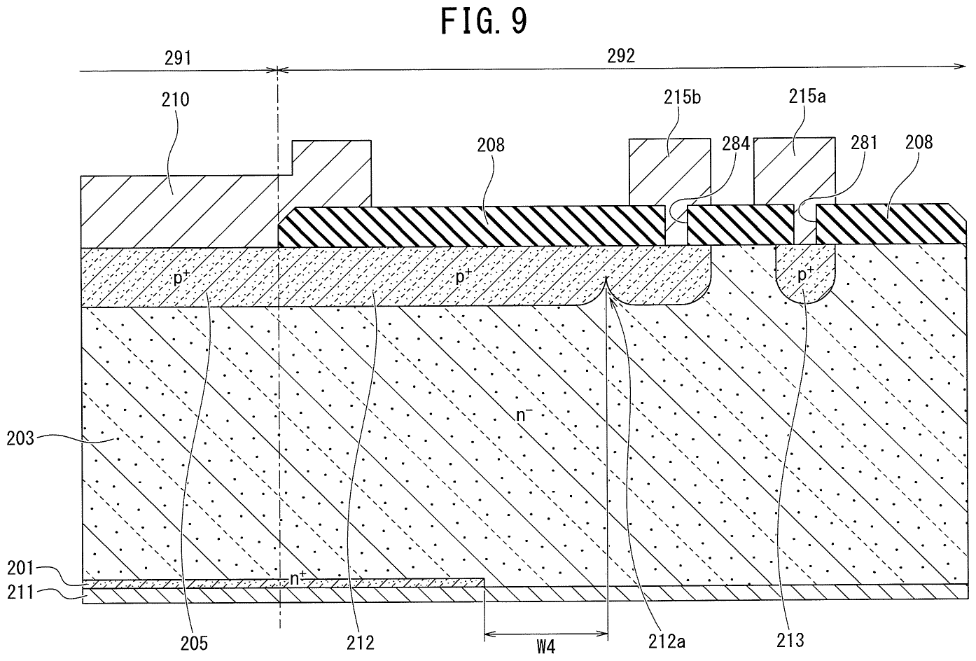

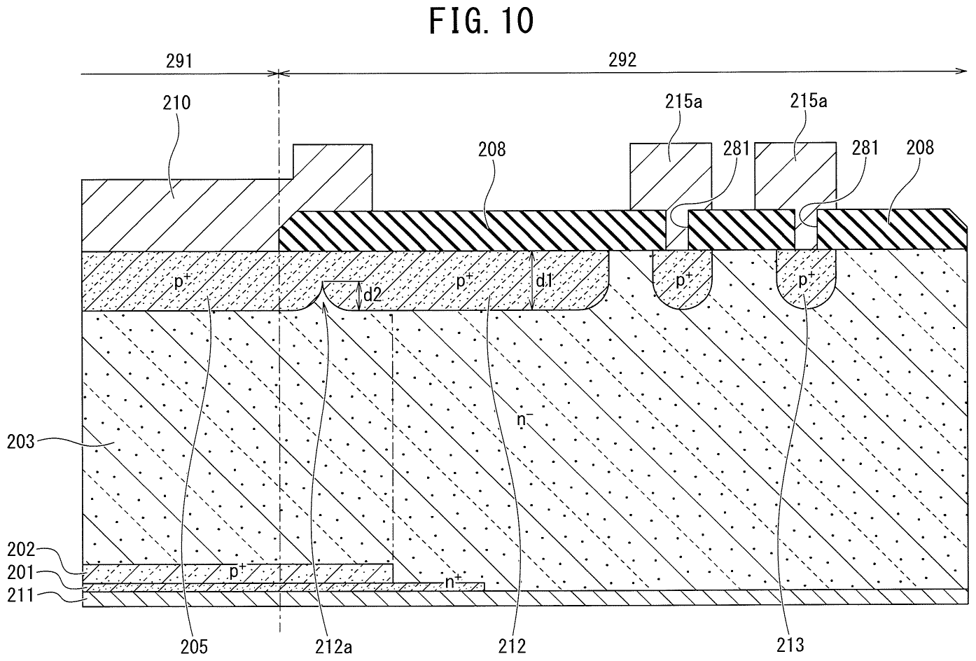

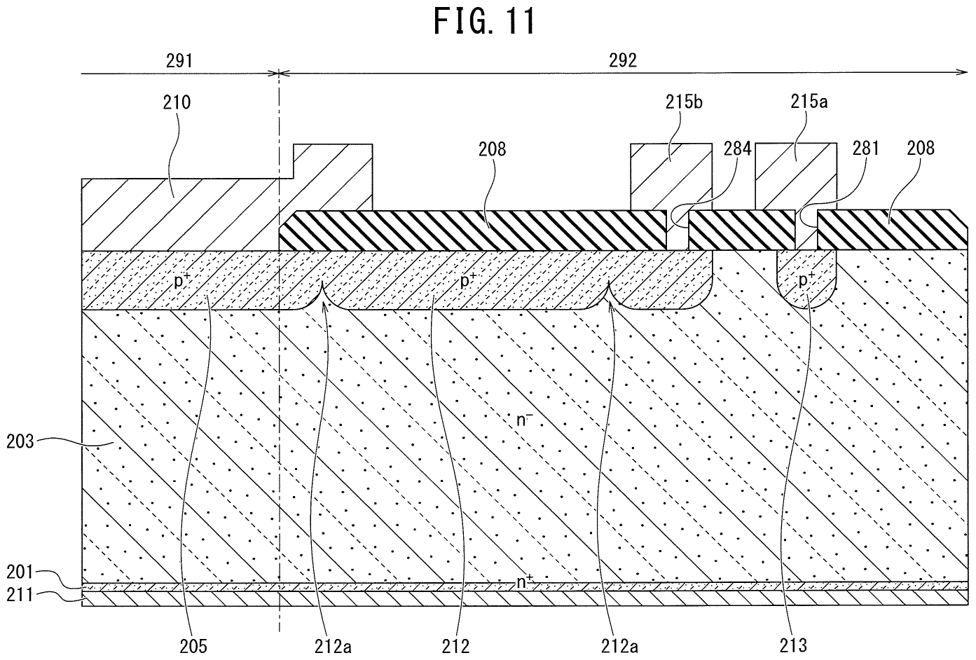

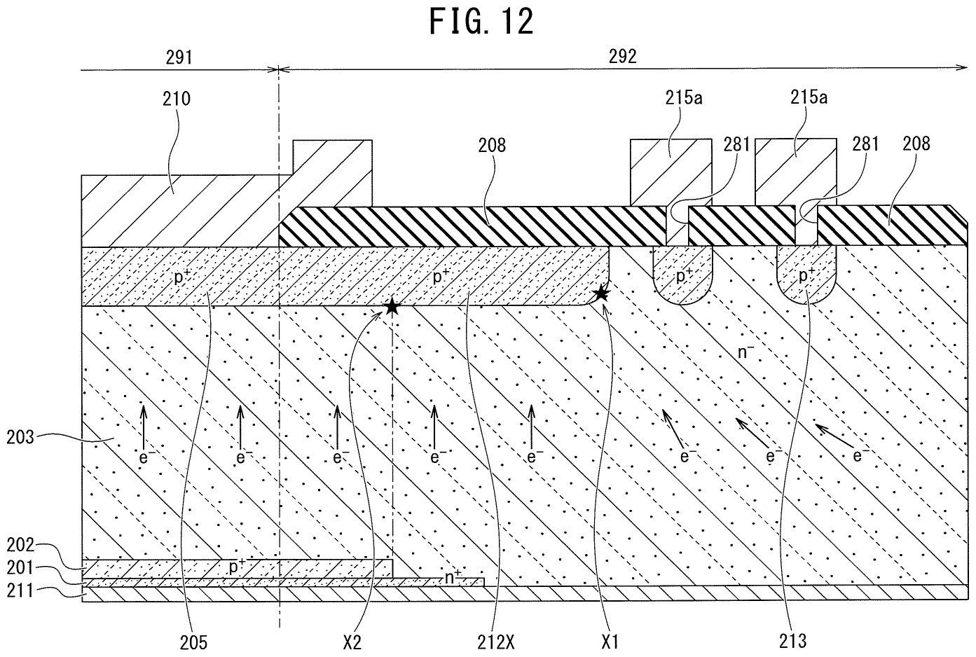

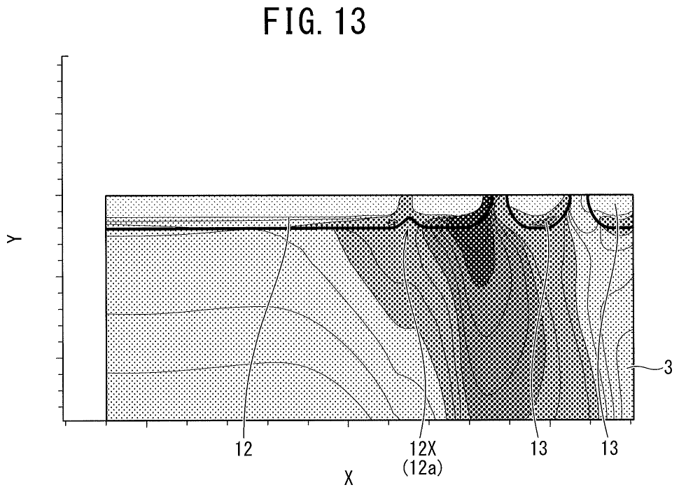

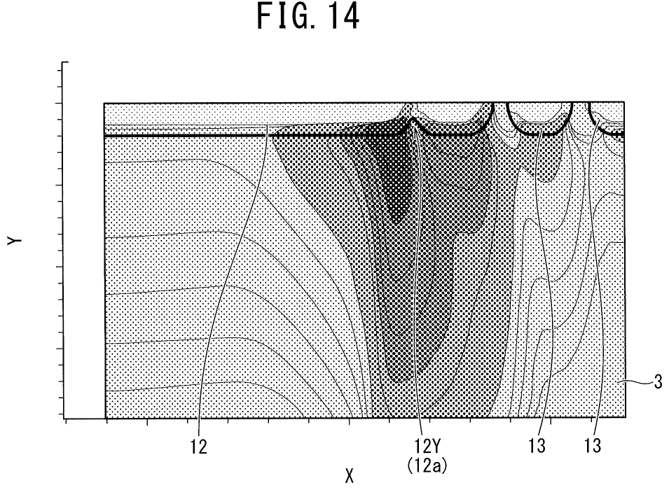

FIG. 3 is a partially enlarged view illustrating a part of an active element illustrated in FIG. 2;

FIG. 4 is a schematic cross-sectional view illustrating a part of a longitudinal cross-sectional configuration of a semiconductor device according to a second embodiment;

FIG. 5 is a schematic cross-sectional view illustrating a part of a longitudinal cross-sectional configuration of a semiconductor device according to a third embodiment;

FIG. 6 is a diagram illustrating a planar configuration of a semiconductor device according to a fourth embodiment;

FIG. 7 is a schematic cross-sectional view illustrating a longitudinal cross-sectional configuration when a cross section is viewed along A-A section line in FIG. 6;

FIG. 8 is a schematic cross-sectional view illustrating a longitudinal cross-sectional configuration of a semiconductor device according to a fifth embodiment;

FIG. 9 is a schematic cross-sectional view illustrating a longitudinal cross-sectional configuration of a semiconductor device according to a sixth embodiment;

FIG. 10 is a schematic cross-sectional view illustrating a longitudinal cross-sectional configuration of a semiconductor device according to a seventh embodiment;

FIG. 11 is a schematic cross-sectional view illustrating a longitudinal cross-sectional configuration of a semiconductor device according to an eighth embodiment;

FIG. 12 is a schematic cross-sectional view illustrating a longitudinal cross-sectional configuration of a semiconductor device according to a comparative example;

FIG. 13 is a diagram illustrating a simulation result of an electric field strength; and

FIG. 14 is a diagram illustrating another simulation result of the electric field strength.

### DETAILED DESCRIPTION

Hereinafter, embodiments of the present disclosure will be described with reference to the drawings. In the description of the drawings, the same or similar parts will be given the same or similar reference numerals and redundant descriptions will be omitted. Meanwhile, the drawing is schematic, and a relationship between a thickness and a planar dimension, a ratio of the thickness of each layer, and the like may be different from the actual values. In addition, the drawings may include portions having different dimensional relationships or ratios. In addition, the embodiments described below exemplify devices and methods for embodying the technical idea of the present disclosure, and the technical idea of the present disclosure does not specify the material, shape, structure, arrangement, and the like of the configuration components in the following embodiments.

In the present specification, a source region of a metal oxide film semiconductor electric field effect transistor (MOSFET) is a “one main region (first main region)” that can be selected as an emitter region of an insulated gate type bipolar transistor (IGBT). In addition, in a thyristor such as a MOS controlled static induction thyristor (SI thyristor), the “one main region” can be selected as a cathode region. A drain region of the MOSFET is an “other main region (second main region)” of a semiconductor device, which is selectable as a collector region in the IGBT and an anode region in the thyristor. In the present specification, the term “main region” simply means any one of the first main region or the second main region, which is appropriate from the technical common sense of those skilled in the art.

In addition, the definitions of directions such as up, down, and the like in the following description are merely definitions for convenience of description and do not limit the technical idea of the present disclosure. For example, it is obvious that, when the target is observed by being rotated by 90°, the up and down are converted into the right and left and read, and when the target is observed by being rotated by 180°, the up and down are inverted and read. In addition, an “upper surface” may be read as a “front surface”, and a “lower surface” may be read as a “back surface”.

In addition, in the following description, a case where a first conductivity type is an n-type and a second conductivity type is a p-type will be described as an example. Meanwhile, the first conductivity type may be selected as a p-type and the second conductivity type may be selected as an n-type by reversing a relationship between the conductivity types. In addition, + or − attached to n or p means that a semiconductor region has a relatively high or low impurity concentration, respectively, as compared with a semiconductor region to which + and − are not added. Meanwhile, even in the semiconductor regions designated by the same n and n, the impurity concentrations of the semiconductor regions do not mean that the impurity concentrations are strictly the same, respectively.

### First Embodiment

### <Structure of Semiconductor Device>

In the present embodiment, a case where a semiconductor device is an IGBT will be described as an example. As illustrated in FIG. 1, a semiconductor device (semiconductor chip) 100 according to a first embodiment includes, for example, an active portion 101 having a rectangular planar shape and a termination region 102 that surrounds the active portion 101 in a plan view. FIG. 2 is a cross-sectional view taken along a direction of the line A-A in FIG. 1 and illustrates a cross-sectional configuration of the active portion 101 and the termination region 102. FIG. 3 is an enlarged view of a part of an active element provided in the active portion 101 illustrated in FIG. 2. As illustrated in FIGS. 2 and 3, the active portion 101 of the semiconductor device 100 includes a trench gate type IGBT as the active element. Hereinafter, the active portion 101 of the active portion 101 and the termination region 102 will be described first. The description will be made by using the active portion 101 side as an inner side and the termination region 102 as an outer side, along a lateral direction.

### <Active Portion>

As illustrated in FIG. 3, a base region 5 of a second conductivity type (p-type) is disposed above a drift layer 3 of a first conductivity type (n⁻-type). An n+-type emitter region 6 having a higher impurity concentration than the drift layer 3 is provided at an upper portion of the base region 5. The impurity concentration in the emitter region 6 is approximately 1×10¹⁹ cm⁻³ or more and approximately 1×10²⁰ cm⁻³ or less. An n-type accumulation layer 4 having a higher impurity concentration than the drift layer 3 is provided at a lower portion of the base region 5. A trench 7 that penetrates the base region 5 and the accumulation layer 4 from an upper surface of the emitter region 6 is provided. The emitter region 6, the base region 5, and the accumulation layer 4 are in contact with a side surface of the trench 7, and a part of the drift layer 3 is further in contact with the side surface. The trench 7 penetrates through the base region 5 and the accumulation layer 4 from the emitter region 6 and reaches the drift layer 3. The trench 7 extends in a direction perpendicular to a plane, and a plurality of trenches 7 is arranged in a stripe shape in a plan view, which is not illustrated. As illustrated in FIG. 2, at least one dummy trench 7a is provided in an outer-side region of the active portion 101. In the example illustrated in FIG. 2, two dummy trenches 7a are provided in the outer-side region of the active portion 101. The dummy trench 7a does not function as an active element.

Although not illustrated, a contact region, which is a second conductivity type (p+-type) semiconductor region having a higher impurity concentration than the base region 5, is provided in an upper portion of the base region 5 illustrated in FIG. 2. The contact region is provided alternately with the emitter region 6 in a direction (a direction perpendicular to the plane in FIG. 3) in which the trench 7 extends in parallel. That is, in a cross section passing through the contact region, a portion of the emitter region 6 in FIG. 3 is the contact region.

A gate insulating film 8a is provided on a bottom surface and the side surface of the trench 7. A gate electrode 9 is embedded inside the trench 7 via the gate insulating film 8a. A trench gate type insulated gate electrode structure (8a, 9) is configured with the gate insulating film 8a and the gate electrode 9. As a material of the gate electrode 9, for example, a polysilicon layer (a doped polysilicon layer) in which a p-type impurity or an n-type impurity is added to a high impurity concentration, or a high melting point metal such as titanium (Ti), tungsten (W), or nickel (Ni) can be used. In the present embodiment, an example in which the gate electrode 9 is formed of a polysilicon layer will be described. As the gate insulating film 8a, in addition to a silicon dioxide (SiO₂) film, a single layer film of any one of a silicon oxynitride (SiON) film, a strontium oxide (SrO) film, a silicon nitride (Si₃N₄) film, an aluminum oxide (Al₂O₃) film, a magnesium oxide (MgO) film, a yttrium oxide (Y₂O₃) film, a hafnium oxide (HfO₂) film, a zirconium oxide (ZrO₂) film, a tantalum oxide (Ta₂O₅) film, and a bismuth oxide (Bi₂O₃) film, a composite film in which a plurality of these, and the like are stacked can be adopted.

An interlayer insulating film 8b is disposed on the gate electrode 9. An emitter surface electrode 10 is provided to cover the interlayer insulating film 8b. The emitter surface electrode 10 is a main electrode that is in contact with a main region. The emitter surface electrode 10 is physically in contact with the emitter region 6 exposed from an opening portion provided in the interlayer insulating film 8b and the contact region (not illustrated). As the interlayer insulating film 8b, a silicon oxide film (BPSG) to which boron (B) and phosphorus (P) are added is used. The interlayer insulating film 8b may be a silicon oxide film (PSG) to which phosphorus (P) is added, a non-doped SiO₂ film which does not contain phosphorus (P) or boron (B) and is referred to as “NSG”, a silicon oxide film (BSG) to which boron (B) is added, a Si₃N₄ film, and the like. In addition, these stacked films may be used. The emitter surface electrode 10 is able to be configured with, for example, a nickel silicide (NiSiₓ) film, a titanium nitride (TiN) film or a titanium (Ti) film, an aluminum (Al) film, an aluminum-silicon (Al—Si) film, or an aluminum-copper (Al—Cu) film. The gate insulating film 8a and the interlayer insulating film 8b may be collectively referred to as an insulating film 8.

A n+-type field stop layer (FS layer) 2 is disposed at a lower surface of the drift layer 3, and a p+-type collector region 1 is disposed at a lower surface of the FS layer 2. A collector back surface electrode 11 is disposed at a lower surface of a collector region 1. As the collector back surface electrode 11, for example, a single layer film consisting of gold (Au) or a metal film in which Ti, nickel (Ni), and Au are stacked in this order can be used.

At an operation of the IGBT according to the first embodiment, for example, the emitter surface electrode 10 is set to an earth potential, and a positive voltage is applied to the collector back surface electrode 11. When the positive voltage equal to or higher than a threshold value is applied to the gate electrode 9, an inversion layer (channel) is formed on the side surface of the trench 7 of the base region 5, and the IGBT is turned on. In an on state, a current flows from the collector back surface electrode 11 to the emitter surface electrode 10 via the collector region 1, the FS layer 2, the drift layer 3, the accumulation layer 4, the inversion layer of the base region 5, and the emitter region 6. When the voltage applied to the gate electrode 9 is less than the threshold value, the inversion layer is not formed in the base region 5, and thus the current does not flow from the collector back surface electrode 11 to the emitter surface electrode 10.

### <Termination Region>

As illustrated in FIG. 2, the drift layer 3 is provided over the active portion 101 and the termination region 102. A boundary between the active portion 101 and the termination region 102 is an inner-side end portion of a gate wiring electrode 16. On an upper surface side of the drift layer 3, a well region 12, a guard ring (field limiting ring) 13 which is a breakdown voltage structure, and a stopper region 14 are provided. All of the well region 12, the guard ring 13, and the stopper region 14 have a second conductivity type (p+-type), are separated from each other by the drift layer 3, and lower surfaces thereof are in contact with the drift layer 3. The stopper region 14 is located on the outer side of the guard ring 13 and surrounds the guard ring 13 in an annular shape in a plan view. The guard ring 13 is located on the outer side of the well region 12 and surrounds the well region 12 in an annular shape in a plan view. An outer-side end portion of the well region 12 is at the termination region 102. The guard ring 13 is a floating diffusion region. A plurality of guard rings 13 may be provided as illustrated in the drawing, and the guard rings 13 are separated from each other by the drift layer 3. Upper surfaces of the drift layer 3, the well region 12, the guard ring 13, and the stopper region 14 are covered with the insulating film 8. A field plate 15a is connected to the upper surface of the guard ring 13 via an opening portion 81 provided at the insulating film 8. The field plate 15a and the opening portion 81 are provided in an annular shape along the guard ring 13 in a plan view. An impurity concentration in both the well region 12 and the guard ring 13 is approximately 1×10¹⁵ cm⁻³ or more and 1×10¹⁹ cm⁻³ or less. The impurity concentration in the well region 12 and the guard ring 13 may be the same as or different from each other. Dimensions of the well region 12 and the guard ring 13 in a depth direction are the same, and may be different from each other. In addition, as illustrated in FIG. 1, the gate wiring electrode 16 is provided in the termination region 102. Hereinafter, the well region 12 and the gate wiring electrode 16 will be described in detail.

### <Well Region and Gate Wiring Electrode>

As illustrated in FIG. 1, the gate wiring electrode 16 surrounds the active portion 101 in an annular shape in a plan view. The gate wiring electrode 16 is electrically connected to the gate electrode 9 of the IGBT illustrated in FIG. 3, and supplies a potential to the gate electrode 9. As illustrated in FIG. 2, the gate wiring electrode 16 is provided on an upper surface side of the well region 12. As a material of the gate wiring electrode 16, for example, a polysilicon layer (a doped polysilicon layer) in which a p-type impurity or an n-type impurity is added to a high impurity concentration, or a high melting point metal such as titanium (Ti), tungsten (W), or nickel (Ni) can be used. In the present embodiment, an example in which the gate wiring electrode 16 is formed of a polysilicon layer will be described.

The well region 12 is an inactive region having an emitter potential. The upper surface of the well region 12 faces the gate wiring electrode 16 via the insulating film 8. The insulating film 8 interposed between the well region 12 and the gate wiring electrode 16 can be formed of the same material as a material constituting the gate insulating film 8a, and may be formed together with the gate insulating film 8a. The well region 12 is provided in an annular shape along the gate electrode 9 in a plan view, and overlaps with the entire gate wiring electrode 16 in a plan view. By providing the well region 12 in this manner, it is possible to suppress an influence of the potential of the gate wiring electrode 16 on a semiconductor layer. For example, when the well region 12 is not provided in the semiconductor region facing the gate wiring electrode 16, there is a possibility that electric field concentration occurs on an end portion of the active portion 101. Therefore, it is preferable to provide the well region 12 in the semiconductor region facing the gate wiring electrode 16. The upper surface of the gate wiring electrode 16 is covered with the insulating film 8, and a gate wiring 18 is provided on the upper surface side of the insulating film 8 in an annular shape along the gate wiring electrode 16 in a plan view. The gate wiring electrode 16 is connected to the gate wiring 18 via the opening portion 82 provided in the insulating film 8. The opening portion 82 may also be provided in an annular shape along the gate wiring electrode 16. The gate wiring 18 is connected to an electrode pad (gate pad) 18A (FIG. 1), and a potential is supplied to the gate wiring electrode 16 via the electrode pad 18A and the gate wiring 18. The gate wiring 18 is able to be configured with, for example, a nickel silicide (NiSiₓ) film, a titanium nitride (TiN) film or a titanium (Ti) film, an aluminum (Al) film, an aluminum-silicon (Al—Si) film, or an aluminum-copper (Al—Cu) film.

An inner-side portion of the well region 12 is electrically connected to the emitter surface electrode 10, and has an emitter potential. An inner-side end portion of the well region 12 is electrically connected to the emitter surface electrode 10 in each of four sides of the square semiconductor chip. For example, as illustrated in FIG. 2, the inner-side end portion of the well region 12 extends to an inside of the active portion 101 and is electrically connected to the emitter surface electrode 10 via the contact region 17 and the opening portion 83 provided in the insulating film 8. The contact region 17 is a second conductivity type (p+-type) region that is provided on an upper surface side of the inner-side end portion of the well region 12, and has an impurity concentration higher than an impurity concentration of the well region 12, and the impurity concentration is approximately 1×10¹⁹ cm⁻³ or more and 1×10²¹ cm⁻³ or less. A charge (hole in the present embodiment) in the well region 12 is pulled out to the emitter surface electrode 10 via the contact region 17 and the opening portion 83. The contact region 17 further extends toward the inner side as illustrated in the drawing and comes into contact with a side surface of the dummy trench 7a. The well region 12 overlaps with at least one dummy trench 7a. When the dimension of the well region 12 in a depth direction is defined as d1, d1 is larger than a depth of the dummy trench 7a. More specifically, d1 is approximately 1.2 times or more and 2 times or less the depth of the dummy trench 7a. Then, d1 is the dimension of the well region 12 in the depth direction at a position at which a recess portion 12a to be described below is not provided. For example, d1 is the maximum depth of the well region 12.

The well region 12 has a recess portion 12a on a lower side (lower surface). By providing the recess portion 12a in the well region 12, concentration of an electric field on the outer-side end portion of the well region 12 is suppressed. The recess portion 12a is located in the termination region 102. The recess portion 12a is located on the outer side of an inner-side end portion of the gate wiring electrode 16 along a direction (lateral direction) perpendicular to the depth direction. In addition, although not illustrated, the recess portion 12a is provided in an annular shape along the well region 12 in a plan view. By providing the recess portion 12a in an annular shape, the concentration of the electric field on the outer-side end portion of the well region 12 is suppressed in the four sides of the semiconductor chip. In the present embodiment, the recess portion 12a is located on the outer side of an outer-side end portion of the gate wiring electrode 16. It is desirable that a depth of the recess portion 12a is not too shallow. When the dimension of the recess portion 12a in a depth direction is defined as d2, for example, d2 is provided to a dimension of ⅓ or more and ⅔ or less of the depth d1 of the well region 12. In addition, in the lateral direction, the dimension of the well region 12 from the recess portion 12a to the outer-side end portion is approximately 2 times or more and 4 times or less the depth d1 of the well region 12. Then, a field plate 15b is provided in a region on the outer side of the recess portion 12a of the well region 12. The field plate 15b is connected to the well region 12 via the opening portion 84 provided in the insulating film 8. The field plate 15b and the opening portion 84 are provided in an annular shape along the well region 12 in a plan view. The field plates 15a and 15b are able to be configured with, for example, a nickel silicide (NiSiₓ) film, a titanium nitride (TiN) film or a titanium (Ti) film, an aluminum (Al) film, an aluminum-silicon (Al—Si) film, or an aluminum-copper (Al—Cu) film.

The well region 12 is formed by ion-implanting an impurity element into the semiconductor layer and performing a heat treatment after the ion-implantation. The impurity element is ion-implanted into a region on the inner side and a region on the outer side from a position at which the recess portion 12a is formed, and then the heat treatment is performed. When the heat treatment is performed, the impurity element is diffused in the semiconductor layer along both the depth direction and the lateral direction, and the region on the inner side of the recess portion 12a and the region on the outer side of the recess portion 12a are connected in the lateral direction, whereby forming the recess portion 12a. In the lateral direction (for example, toward the outer side), when a dimension in the lateral direction from the inner-side end portion to the outer-side end portion of the gate wiring electrode 16 is defined as W1 and a dimension in the lateral direction from a position at which the inner-side end portion of the gate wiring electrode 16 is located to a position at which the recess portion 12a is located is defined as W2, a relationship of W2>W1+C × d1 is satisfied. The constant C is a value of approximately 0.75 or more and 0.85 or less, and “C×d1” represents a distance over which the impurity implanted by ion-implantation diffuses in the lateral direction by the heat treatment. The well region 12 is able to be reliably formed to overlap with the entire gate wiring electrode 16 by ion-implanting the impurity into a region including at least the range of W1 illustrated in the drawing. In consideration of the above, by providing the recess portion 12a at a position at which W2≥W1+C×d1 is satisfied, the well region 12 is provided to reliably overlap with the entire gate wiring electrode 16, and then the concentration of the electric field on the outer-side end portion of the well region 12 is able to be suppressed.

### Main Effects of First Embodiment

The electric field was likely to be concentrated on the outer-side end portion of the p-type region (for example, well region) of the termination region 102. In addition, since the dimension in the lateral direction of the well region is determined according to the dimension of the gate wiring electrode 16 in the lateral direction, when a current filament is generated at the outer-side end portion of the well region, the current filament was not easily moved to the emitter surface electrode 10. More specifically, when the gate wiring electrode 16 surrounding the active portion 101 in a plan view is provided, the well region of which the upper surface faces the gate wiring electrode 16 is provided to suppress an influence of the potential of the gate wiring electrode 16 on the semiconductor layer. The dimension in the lateral direction of the well region is provided to be larger than at least the dimension of the gate wiring electrode 16 in the lateral direction. Therefore, the dimension from the outer-side end portion to the inner-side end portion of the well region electrically connected to the emitter surface electrode 10 is larger than when the gate wiring electrode 16 is not provided, and the distance over which the holes moves to the emitter surface electrode 10 is longer. Then, the longer the moving distance, the harder for the holes to flow to the emitter surface electrode 10. In this manner, when the moving distance is long, hole extraction characteristics are different from those when the moving distance is short.

In the semiconductor device 100 according to the first embodiment, since the recess portion 12a is provided on the lower side of the well region 12, it is possible to suppress the concentration of the electric field on the outer-side end portion of the well region 12, and it is possible to move a position at which the electric field is concentrated from the outer-side end portion of the well region 12 to the inside of the active portion 101. Therefore, the position at which the electric field is concentrated is able to be moved from the termination region 102 to the inside of the active portion 101. Therefore, it is possible to suppress a decrease in breakdown voltage performance of the semiconductor device 100. For example, the breakdown voltage performance of the semiconductor device 100 is able to be improved. It is desirable that a current filament during an electric field concentration and an avalanche operation is generated in the active portion 101 of the active portion 101 and the termination region 102. When the electric field is concentrated inside the active portion 101, even when a local filament current is generated in a certain trench, when a temperature of the trench is increased, hopping in which the current filament moves to another trench 7 is likely to occur. In this manner, when the electric field is concentrated on the active portion 101, the current filament does not remain at one place, so that destruction is unlikely to occur.

In addition, in the semiconductor device 100 according to the first embodiment, the recess portion 12a is located on the outer side of the inner-side end portion of the gate wiring electrode 16 along the lateral direction. Therefore, it is possible to reliably provide a portion of the well region 12 that extends on the inner side of the inner-side end portion of the gate wiring electrode 16. Therefore, a region from an inner-side end portion of the gate wiring electrode 16 to a trench on the most outer side of the active portion 101 is able to be reliably covered with the well region 12, and a region up to a connection position (opening portion 83) with the emitter surface electrode 10 is able to be reliably covered with the well region 12. Therefore, it is possible to suppress a decrease in the breakdown voltage performance of the outer-side end portion of the active portion 101, and it is possible to reliably electrically connect the well region 12 to the emitter surface electrode 10.

In addition, in the semiconductor device 100 according to the first embodiment, the recess portion 12a is located on the outer side of the outer-side end portion of the gate wiring electrode 16 along the lateral direction. Since the recess portion 12a is located near the outer-side end portion of the well region 12, which is a position at which the electric field is likely to be concentrated, it is possible to efficiently suppress the concentration of the electric field on the outer-side end portion of the well region 12.

In addition, in the semiconductor device 100 according to the first embodiment, the dimension W2 from the inner-side end portion of the gate wiring electrode 16 to a position at which the recess portion 12a is located satisfies a relationship of W2>W1+C×d1. Therefore, it is possible to suppress the concentration of the electric field on the outer-side end portion of the well region 12 while the well region 12 is provided to reliably overlap with the entire gate wiring electrode 16.

In addition, in the semiconductor device 100 according to the first embodiment, the dimension d2 of the recess portion 12a in the depth direction is ⅓ or more and ⅔ or less of the dimension d1 of the well region 12 in the depth direction. By providing the recess portion 12a at a depth that is not too shallow, it is possible to efficiently suppress the concentration of the electric field on the outer-side end portion of the well region 12.

In addition, in the semiconductor device 100 according to the first embodiment, the field plate 15b is provided in the region on the outer side of the recess portion 12a of the well region 12. By providing the field plate 15b, the breakdown voltage performance of the termination region 102 is able to be improved, as compared with a case where the field plate 15b is not provided.

### Second Embodiment

In the semiconductor device 100 according to the first embodiment, the recess portion 12a is located on the outer side of the outer-side end portion of the gate wiring electrode 16 as illustrated in FIG. 2, but in the semiconductor device 100 according to a second embodiment, the recess portion 12a is located on the inner side of the outer-side end portion of the gate wiring electrode 16 as illustrated in FIG. 4. In addition, in the present embodiment, when a dimension in the lateral direction from a position of the inner-side end portion of the gate wiring electrode 16 to a position of the outer-side end portion of the well region 12 is defined as W3, a relationship of W3>W1+C×d1 is satisfied. Since the recess portion 12a is located on the inner side of the outer-side end portion of the gate wiring electrode 16, W3 is able to be provided to be smaller than in the first embodiment.

### «Main Effects of Second Embodiment»

With the semiconductor device 100 according to the second embodiment as well, the same effects as the effects of the semiconductor device 100 according to the first embodiment are obtained.

In addition, in the semiconductor device 100 according to the second embodiment, the recess portion 12a is located on the inner side of the outer-side end portion of the gate wiring electrode 16. Therefore, the recess portion 12a is closer to the active portion 101 than the first embodiment. When the recess portion 12a is close to the active portion 101, the current filament is easily moved to the active portion 101 even when the electric field is concentrated in the vicinity of the recess portion 12a and the current filament is generated. In addition, when the recess portion 12a is close to the active portion 101, the hole is easily pulled out from the contact region 17.

In addition, in the semiconductor device 100 according to the second embodiment, the recess portion 12a is located on the inner side of the outer-side end portion of the gate wiring electrode 16, so that the dimension of W3 is able to be reduced as compared with the first embodiment. Therefore, a dimension of the well region 12 in the lateral direction is small, and it is space saving. In addition, when the dimension of the well region 12 in the lateral direction is able to be reduced, the number of guard rings 13 is able to be increased as illustrated in FIG. 4, and breakdown voltage performance is able to be improved.

### Third Embodiment

In the semiconductor device 100 according to the first embodiment and the semiconductor device 100 according to the second embodiment, as illustrated in FIGS. 2 and 4, the well region 12 has a single recess portion 12a on the lower side, but in the semiconductor device 100 according to a third embodiment illustrated in FIG. 5, the well region 12 has a plurality of recess portions 12a on the lower side. One recess portion 12a is located on the outer side of another recess portions 12a.

In the example illustrated in FIG. 5, the well region 12 according to the third embodiment has two recess portions 12a. One of the two recess portions 12a is located on the outer side of the other in the lateral direction. More specifically, one of the two recess portions 12a is located on the outer side of the outer-side end portion of the gate wiring electrode 16, and the other is located on the inner side of the outer-side end portion of the gate wiring electrode 16. In order to distinguish the recess portion 12a located on the outer side of the outer-side end portion of the gate wiring electrode 16 from the recess portion 12a located on the inner side of the outer-side end portion of the gate wiring electrode 16, the recess portion located on the outer side of the outer-side end portion of the gate wiring electrode 16 is referred to as a first recess portion 12a1, and the recess portion located on the inner side of the outer-side end portion of the gate wiring electrode 16 is referred to as a second recess portion 12a2. When the first recess portion 12al and the second recess portion 12a2 are not distinguished from each other, the first recess portion 12al and the second recess portion 12a2 are simply referred to as the recess portion 12a.

When a dimension of the second recess portion 12a2 in the depth direction is defined as d3, for example, d3 is set to a dimension of ⅓ or more and ⅔ or less of the depth d1 of the well region 12. In the present embodiment, d3 has the same dimension as d2 in the depth direction of the first recess portion 12al.

### «Main Effects of Third Embodiment»

With the semiconductor device 100 according to the third embodiment as well, the same effects as the effects of the semiconductor device 100 according to the first embodiment and the semiconductor device 100 according to the second embodiment are obtained.

The recess portion 12a may be at any position on the outer side of the inner-side end portion of the gate wiring electrode 16 and on the inner side of the outer-side end portion of the well region 12. The number of the recess portions 12a is not limited to two, and may be three or more.

### «Modification Example of Third Embodiment»

Hereinafter, a modification example of the third embodiment will be described. In the modification example of the third embodiment, the dimension d3 of the second recess portion 12a2 in the depth direction is provided to be larger than the dimension d2 of the first recess portion 12al in the depth direction (d3>d2). By forming the second recess portion 12a2 on the inner side to be deeper than the first recess portion 12al on the outer side, among the first recess portion 12al and the second recess portion 12a2, the electric field is more easily concentrated on the second recess portion 12a2 on the inner side than the first recess portion 12al on the outer side. When the electric field is concentrated on the second recess portion 12a2 on the inner side, it is easy to move the current of the current filament to the active portion 101.

In the first to third embodiments, the position of the recess portion 12a in the lateral direction may be determined with reference to the deepest portion (center portion) of the recess portion 12a. For example, it may be determined that the deepest portion (center portion) of the recess portion 12a is located on the outer side of the inner-side end portion of the gate wiring electrode 16. In addition, for example, it may be determined that the deepest portion of the recess portion 12a is located on the inner side or the outer side of the outer-side end portion of the gate wiring electrode 16. In addition, for example, a dimension in the lateral direction from a position of the inner-side end portion of the gate wiring electrode 16 to a position of the deepest portion of the recess portion 12a may be defined as W2.

In addition, in the first to third embodiments described above, the dimensions d2 and d3 of the recess portion 12a in the depth direction may be dimensions of the recess portion 12a at the deepest position (center portion) in the depth direction.

In addition, in the first to third embodiments described above, in the heat treatment when forming the well region 12, end portions of each of a region on the inner side and a region on the outer side from a position at which the recess portion 12a is formed are connected to each other in a state of having a curvature. Then, a cross-sectional shape of the formed recess portion 12a may be, for example, a V-shape as illustrated in the drawings.

### Fourth Embodiment

In the present specification, in a diode, “one main region (first main region)” can be selected as a cathode region, and an “other main region (second main region)” can be selected as an anode region. In the present specification, the term “main region” simply means any one of the first main region or the second main region, which is appropriate from the technical common sense of those skilled in the art.

### <Structure of Semiconductor Device>

In the present embodiment, a case where a semiconductor device is a diode will be described as an example. The diode is used as, for example, a freewheeling diode. In addition, examples of the semiconductor device include a diode having a pn junction, a JBS diode, an MPS diode, a Schottky diode, and the like. As illustrated in FIG. 6, a semiconductor device (semiconductor chip) 200 according to a fourth embodiment includes, for example, an active portion 291 having a rectangular planar shape and a termination region 292 surrounding the active portion 291 in a plan view. In the present embodiment, a boundary between the active portion 291 and the termination region 292 is an inner-side end portion of an interlayer insulating film 208 to be described below.

FIG. 7 is a cross-sectional view taken along a direction of the line A-A in FIG. 6 and illustrates a cross-sectional configuration of the active portion 291 and the termination region 292. The description will be made with the active portion 291 side as an inner side and the termination region 292 as an outer side along the lateral direction. A drift layer 203, which is a first conductivity type (n⁻-type) semiconductor region, is provided over the active portion 291 and the termination region 292.

On an upper surface side of the drift layer 203, an anode region 205 which is a second conductivity type (p+-type) semiconductor region, an inactive region 212 which is a second conductivity type (p+-type) semiconductor region, and a guard ring (field limiting ring) 213 which is a second conductivity type (p+-type) semiconductor region are provided. The anode region 205 is an example of a first region, and the inactive region 212 is an example of a second region. Lower surfaces of the anode region 205, the inactive region 212, and the guard ring 213 are in contact with the drift layer 203. An impurity concentration in the anode region 205 is approximately 1.0×10¹³ cm⁻³ or more and 1.0×10¹⁹ cm⁻³ or less. An impurity concentration in the inactive region 212 is approximately 1.0×10¹³ cm⁻³ or more and 1.0×10¹⁹ cm⁻³ or less. An impurity concentration in the guard ring 213 is approximately 1.0×10¹³ cm⁻³ or more and 1.0×10¹⁹ cm-3 or less. A plurality of guard rings 213 may be provided.

The anode region 205 is provided at the active portion 291, and the inactive region 212 and the guard ring 213 are provided at the termination region 292. The anode region 205 and the inactive region 212 are in contact with the drift layer 203 in a thickness direction to form a pn junction. An anode surface electrode 210 that is physically in contact with the anode region 205 is provided on an upper surface of the anode region 205. The anode region 205 is, for example, a contact region. In order to reduce a contact resistance with the anode surface electrode 210 of the anode, a high-concentration p-type region may be provided on the surface of the anode region 205. The anode surface electrode 210 is able to be configured with, for example, a nickel silicide (NiSiₓ) film, a titanium nitride (TiN) film or a titanium (Ti) film, an aluminum (Al) film, an aluminum-silicon (Al—Si) film, or an aluminum-copper (Al—Cu) film.

The inactive region 212 is provided to improve breakdown voltage performance of the semiconductor device 200. The inactive region 212 surrounds the anode region 205 in an annular shape in the plan view. An inner-side end portion of the inactive region 212 is in contact with an outer-side end portion of the anode region 205. For example, the inactive region 212 may be formed continuously and integrally with the anode region 205. In addition, a dimension of the inactive region 212 in the depth direction may be the same dimension as a dimension of the anode region 205 in the depth direction. A charge in the inactive region 212 is pulled out to the anode surface electrode 210, for example, via the anode region 205.

The inactive region 212 has a recess portion 212a on a lower side (lower surface). By providing the recess portion 212a in the inactive region 212, concentration of an electric field on an outer-side end portion of the inactive region 212 is suppressed. The recess portion 212a is located in the termination region 292. In addition, for example, as illustrated in FIG. 6, the recess portion 212a is provided in an annular shape at the termination region 292 in the plan view. More specifically, the recess portion 212a is provided in an annular shape along the inactive region 212 provided in the termination region 292. The recess portion 212a may be provided in an annular shape in the plan view, and is not limited to the shape illustrated in FIG. 6. By providing the recess portion 212a in an annular shape, the concentration of the electric field on the outer-side end portion of the inactive region 212 is suppressed at four sides of the semiconductor chip. It is desirable that a depth of the recess portion 212a is not too shallow. When the depth of the recess portion 212a is too shallow, the influence of the recess portion 212a on the electric field is too small, and the influence on changing the position at which the electric field is concentrated is too small. As illustrated in FIG. 7, a dimension in the depth direction at a position at which the recess portion 212a is not provided in the inactive region 212 is d1, and a dimension in the depth direction of the recess portion 212a is d2. More specifically, a dimension in the depth direction at the deepest position (center portion) of the recess portion 212a is defined as d2. Then, for example, d2 is provided to a dimension of ⅓ or more and ⅔ or less of the depth d1 of the inactive region 212 (d⅓≤d2≤2d⅓). Therefore, the dimension d2 of the inactive region 212 at the deepest position of the recess portion 212a in the depth direction is a dimension larger than ⅓ and smaller than ⅔ of the depth d1.

In the lateral direction, the recess portion 212a may be provided at a position closer to the outer-side end portion of the inactive region 212. In addition, in the lateral direction, a dimension of the inactive region 212 from the recess portion 212a to the outer-side end portion may be approximately 2 times or more and 4 times or less the depth d1 of the inactive region 212.

The inactive region 212 is formed by ion-implanting an impurity element into the semiconductor layer and performing a heat treatment after the ion-implantation. The impurity element is ion-implanted into a region on the inner side and a region on the outer side from a position at which the recess portion 212a is formed, and then the heat treatment is performed. When the heat treatment is performed, the impurity element is diffused in the semiconductor layer along both the depth direction and the lateral direction, and the region on the inner side of the recess portion 212a and the region on the outer side of the recess portion 212a are connected in the lateral direction, whereby forming the recess portion 212a. In this case, the respective end portions of the region on the inner side and the region on the outer side are connected to each other in a state of having a curvature. Then, a cross-sectional shape of the formed recess portion 212a may be, for example, a V-shape as illustrated in the drawings. In addition, it is required that a variation in diffusion due to the ion-implantation and the heat treatment is small.

The interlayer insulating film 208 that is physically in contact with the inactive region 212 is provided on an upper surface of the inactive region 212. Although not illustrated, the interlayer insulating film 208 is provided to surround the active portion 291 in the plan view. An outer-side end portion of the interlayer insulating film 208 is provided up to a chip end portion of the semiconductor device 200 and is in contact with upper surfaces of the guard ring 213 and the drift layer 203 of the termination region 292. As the interlayer insulating film 208, a silicon oxide film (BPSG) to which boron (B) and phosphorus (P) are added is used. The interlayer insulating film 208 may be a silicon oxide film (PSG) to which phosphorus (P) is added, a non-doped SiO₂ film which does not contain phosphorus (P) or boron (B) and is referred to as “NSG”, a silicon oxide film (BSG) to which boron (B) is added, a Si₃N₄ film, and the like. In addition, these stacked films may be used. The interlayer insulating film 208 may be simply referred to as an insulating film.

A field plate 215b is provided in a region on the outer side of the recess portion 212a of the inactive region 212. The field plate 215b is connected to the inactive region 212 via the opening portion 284 provided in the interlayer insulating film 208. A configuration of the field plate 215b is the same as the configuration of the field plate 15b described in the first embodiment, and thus the detailed description thereof will be omitted.

The guard ring 213 is located on the outer side of the inactive region 212 and surrounds the inactive region 212 in an annular shape in the plan view. The guard ring 213 is a floating diffusion region, and is separated from the inactive region 212 by the drift layer 203. A configuration of the guard ring 213 is the same as the configuration of the guard ring 13 described in the first embodiment, and thus the detailed description thereof will be omitted. A field plate 215a is connected to an upper surface of the guard ring 213 via an opening portion 281 provided at the interlayer insulating film 208. A configuration of the field plate 215a is the same as the configuration of the field plate 15a described in the first embodiment, and thus the detailed description thereof will be omitted.

A cathode region 201, which is a first conductivity type (n+) semiconductor region having a higher impurity concentration than the drift layer 203, is provided on a lower surface side of the drift layer 203. The cathode region 201 is an example of a third region. An impurity concentration in the cathode region 201 is approximately 1.0 × 1014 cm⁻³ or more and approximately 1.0 × 10¹⁸ cm⁻³ or less. The cathode region 201 is provided over the entire lower surface of the drift layer 203. An upper surface of the cathode region 201 is in contact with the drift layer 203. A cathode back surface electrode 211 is disposed on a lower surface of the cathode region 201. A configuration of the cathode back surface electrode 211 is the same as the configuration of the collector back surface electrode 11, and thus the detailed description thereof will be omitted.

### «Main Effects of Fourth Embodiment»

Hereinafter, the main effects of the semiconductor device 200 according to the fourth embodiment will be described, but the outline of the present technology will be described before that. A vertical high-breakdown voltage semiconductor device such as a diode has a breakdown voltage withstanding structure in a peripheral portion of a semiconductor substrate to secure a breakdown voltage. In a case of reverse bias, carriers on a lower side of the breakdown voltage withstanding structure of the diode are concentrated on the anode end portion. Therefore, the electric field strength at the anode end portion is increased, and an avalanche (reverse recovery current) is likely to occur. As a structure for avoiding this phenomenon, there is a HiRC structure (inactive region) described in JP 3444081 B. In the HiRC structure, a p-type semiconductor region having no contact region is provided between an edge portion and the active portion. Therefore, the carrier on the lower side of the breakdown voltage withstanding structure region is able to be received by the HiRC structure to relax the electric field. Therefore, the occurrence of an avalanche at the anode end portion is suppressed.

In this manner, by providing the HiRC structure having a certain length in the lateral direction, the region for receiving the carrier is able to be widened. Meanwhile, even when the electric field is relaxed by pulling out a certain amount of carriers by the HiRC structure, the local electric field concentration may occur on the outer peripheral portion of the HiRC structure when an avalanche occurs. For example, according to the inactive region 212X according to the comparative example illustrated in FIG. 12, when an avalanche occurs, a local electric field concentration may occur on the position of the star mark X1.

In addition, since the HiRC structure does not contribute to electron conduction, it is desirable to provide the HiRC structure to be short to save a space. Meanwhile, when the HiRC structure is shortened, a region for pulling out the carrier is narrowed, and the electric field is likely to be concentrated. Therefore, it is difficult to shorten the HiRC structure.

On the other hand, in the semiconductor device 200 according to the forth embodiment, as illustrated in FIG. 7, since the recess portion 212a is provided on the lower side of the inactive region 212, it is possible to suppress the concentration of the electric field locally on the outer-side end portion of the inactive region 212 at the time of avalanche, and it is possible to improve a reverse recovery tolerance. Therefore, it is possible to suppress a decrease in breakdown voltage performance of the semiconductor device 200. For example, the breakdown voltage performance of the semiconductor device 200 is able to be improved. Then, a position at which the electric field is concentrated is able to be moved from the outer-side end portion of the inactive region 212 toward the active portion 291. Therefore, the avalanche current is able to be generated in the active portion 291 having a relatively high resistance to the avalanche current due to the wide area.

In addition, a region on the inner side and a region on the outer side from the deepest position of the recess portion 212a in the inactive region 212 are connected to each other in a state of having a curvature. Therefore, the equipotential line extends toward the guard ring 213, and the electric field concentration on the outer-side end portion of the inactive region 212 is relaxed.

In addition, in the semiconductor device 200 according to the forth embodiment, by providing the recess portion 212a on the lower side of the inactive region 212, local temperature concentration is less likely to occur, and the reverse recovery tolerance is able to be improved. Therefore, it is possible to shorten a length of the inactive region 212 in the lateral direction while ensuring the same breakdown voltage amount. Therefore, a width (edge length) of the termination region 292 is able to be reduced, and a chip size is able to be reduced.

In addition, in the semiconductor device 200 according to the fourth embodiment, the recess portion 212a is provided near the outer-side end portion of the inactive region 212 at which the electric field is likely to be concentrated, and thus the concentration of the electric field on the outer-side end portion of the inactive region 212 is able to be efficiently suppressed. More specifically, even when the cathode region 201 is provided on the entire lower surface of the drift layer 203, it is possible to efficiently suppress the concentration of the electric field on the outer-side end portion of the inactive region 212. An area of the inactive region 212 is able to be narrowed by providing the recess portion 212a, thereby the resistance value is able to be increased, and the current path flowing to the inactive region 212 is able to be narrowed.

In addition, in the semiconductor device 200 according to the fourth embodiment, the dimension d2 of the recess portion 212a in the depth direction is ⅓ or more and ⅔ or less of the dimension d1 of the inactive region 212 in the depth direction. By providing the recess portion 212a at a depth that is not too shallow, the influence of the recess portion 212a on the electric field is not excessively reduced, and thus the concentration of the electric field on the outer-side end portion of the inactive region 212 is able to be efficiently suppressed.

In addition, in the semiconductor device 200 according to the fourth embodiment, the field plate 215b is provided in a region on the outer side of the recess portion 212a of the inactive region 212. By providing the field plate 215b, breakdown voltage performance of the termination region 292 is able to be improved, as compared with a case where the field plate 215b is not provided.

### Fifth Embodiment

In the semiconductor device 200 according to the fourth embodiment, as illustrated in FIG. 7, the cathode region 201 is provided over the entire lower surface of the drift layer 203, but the present technology is not limited to this. In the semiconductor device 200 according to a fifth embodiment, the cathode region 201 is provided only at a center portion of the semiconductor device 200 in a plan view, and the cathode region 201 is not provided up to a chip end portion of the semiconductor device 200 as illustrated in FIG. 8. More specifically, an outer-side end portion of the cathode region 201 is located on the outer side of an outer-side end portion of the anode region 205 and on the inner side of an outer-side end portion of the drift layer 203. In addition, in the semiconductor device 200 according to the fifth embodiment, the recess portion 212a is located on the inner side of the outer-side end portion of the cathode region 201 as illustrated in FIG. 8. More specifically, the deepest portion of the recess portion 212a is located on the inner side of the outer-side end portion of the cathode region 201.

The cathode region 201 is a main supply source of carriers (electrons). Therefore, many carriers enter the diode through the cathode region 201. The reason why the cathode region 201 is not provided up to the outer-side end portion of the drift layer 203 in the present embodiment is to reduce the carriers that fill the chip outer peripheral portion side. In this manner, in the configuration of the cathode region 201 of the present embodiment, the carriers are able to be collected on the active portion 291 side. In addition, the outer-side end portion of the inactive region 212 may be, for example, on the outer side of the outer-side end portion of the cathode region 201, that is, in a region in which the carrier is reduced.

In addition, in the present embodiment, the recess portion 212a is provided on the inner side of the outer-side end portion of the cathode region 201. By bringing the recess portion 12a close to the active portion 291, the carriers collected on the active portion 291 side by the cathode region 201 are more likely to move to the active portion 291 side. As a result, the carriers are easily pulled out from the anode region 205.

### «Main Effects of Fifth Embodiment»

With the semiconductor device 200 according to the fifth embodiment as well, the same effects as the effects of the semiconductor device 200 according to the fourth embodiment are obtained. In addition, in the semiconductor device 200 according to the fifth embodiment, since the recess portion 212a is provided on the inner side of the outer-side end portion of the cathode region 201, the carriers collected on the active portion 291 side by the cathode region 201 are more likely to move to the active portion 291 side. In this manner, by providing a significant point of electric field concentration and pulling out a current from the significant point, it is possible to create a carrier path as close as possible to the active portion. When an avalanche current is generated in the active portion 291, the current concentration point is likely to move in the active portion 291 with an increase in the lattice temperature, so that destruction is unlikely to occur.

### Sixth Embodiment

In the semiconductor device 200 according to the fifth embodiment illustrated in FIG. 8, the recess portion 212a is provided on the inner side of the outer-side end portion of the cathode region 201, but the present technology is not limited thereto. In the semiconductor device 200 according to a sixth embodiment, as illustrated in FIG. 9, the recess portion 212a is provided on the outer side of the outer-side end portion of the cathode region 201. More specifically, the deepest portion of the recess portion 212a is located on the outer side of the outer-side end portion of the cathode region 201. The description of the same configuration as the semiconductor device 200 according to the fifth embodiment will be omitted.

The outer-side end portion of the cathode region 201 is located on the inner side of the outer-side end portion of the drift layer 203. In addition, the outer-side end portion of the cathode region 201 may be, for example, on the outer side of an outer-side end portion of the anode region 205. The outer-side end portion of the inactive region 212 is located on the outer side of the outer-side end portion of the cathode region 201. Hereinafter, a distance from the outer-side end portion of the cathode region 201 to the recess portion 212a will be described in detail.

When a dimension in the lateral direction from a position of the outer-side end portion of the cathode region 201 to a position of the recess portion 212a in the lateral direction is defined as W4, a relationship of C×d1<W4<20 μm is satisfied. The constant C is a value of approximately 0.75 or more and 0.85 or less, and “C×d1” represents a distance over which the impurity implanted by ion-implantation diffuses in the lateral direction by the heat treatment. By ion-implanting an impurity into at least a range of the drift layer 203 overlapping with the cathode region 201, the inactive region 212 is able to be reliably formed to a position at which the outer-side end portion of the cathode region 201 is present in a plan view. In addition, by providing the recess portion 12a at a position at which C×d1<W4 <20 μm is satisfied, it is possible to suppress the concentration of the electric field on the outer-side end portion of the inactive region 212 while receiving the carriers supplied from the cathode region 201 in the inactive region 212. The dimension W4 may be a dimension from a position at which the outer-side end portion of the cathode region 201 is present to the deepest position (center portion) of the recess portion 212a.

### «Main Effects of Sixth Embodiment»

With the semiconductor device 200 according to the sixth embodiment as well, the same effects as the effects of the semiconductor device 200 according to fourth embodiment are obtained.

In addition, in the semiconductor device 200 according to the sixth embodiment, the dimension W4 from a position of the outer-side end portion of the cathode region 201 to a position of the recess portion 212a satisfies a relationship of C×d1<W4<20 μm. Therefore, the inactive region 212 is able to be reliably formed up to a position at which the outer-side end portion of the cathode region 201 is present, and it is possible to suppress the concentration of the electric field on the outer-side end portion of the inactive region 212 while receiving the carriers supplied from the cathode region 201 in the inactive region 212.

### Seventh Embodiment

As illustrated in FIG. 10, a semiconductor device 200 according to a seventh embodiment includes a p-type region 202 that is provided in a layered manner on an upper surface side of a cathode region 201 and is a second conductivity type (p-type) semiconductor region. The recess portion 212a is located on the inner side of an outer-side end portion of the p-type region 202.

The p-type region 202 is provided to suppress a surge voltage, and has a function of reducing a current at a short circuit. The p-type region 202 may be in a floating state or may be in contact with the cathode back surface electrode 211. The drift layer 203 is interposed between the p-type region 202 and the inactive region 212. In addition, the outer-side end portion of the p-type region 202 is located on the outer side of the outer-side end portion of the anode region 205 and is located on the inner side of the outer-side end portion of the inactive region 212 and the outer-side end portion of the cathode region 201. The p-type region 202 is an example of a fourth region. An impurity concentration of the p-type region 202 is approximately 1.0×10¹⁵ cm⁻³ or more and 1.0×10¹⁸ cm⁻³ or less.

It is found that when a semiconductor region is provided on a lower side of the drift layer 203 and a boundary of the semiconductor region overlaps with the inactive region 212 in a plan view, an electric field is concentrated on a position overlapping with the boundary of the inactive region 212. For example, it is found that when the p-type region 202 is present on the lower surface side of the drift layer 203, the electric field is concentrated on a portion of the inactive region 212 that overlaps with the outer-side end portion of the p-type region 202 in the plan view. More specifically, it is found that the electric field is concentrated on positions of star marks X2 illustrated in FIG. 12. Therefore, as illustrated in FIG. 10, the position of the recess portion 212a is adjusted, and the recess portion 212a is provided on the inner side of the outer-side end portion of the p-type region 202 and on the outer side of the outer-side end portion of the anode region 205. More specifically, the deepest portion (center portion) of the recess portion 212a is provided to be on the inner side of the outer-side end portion of the p-type region 202 and the outer side of the outer-side end portion of the anode region 205. Therefore, at least a part of the current concentrated on a portion of the inactive region 212 immediately above the outer-side end portion of the p-type region 202 is able to be dispersed to other portions. More specifically, a part of the current is able to be dispersed to a position closer to the active portion 291 from the outer-side end portion of the p-type region 202.

### «Main Effects of Seventh Embodiment»

With the semiconductor device 200 according to the seventh embodiment as well, the same effects as the effects of the semiconductor device 200 according to the fourth embodiment are obtained. In addition, in the semiconductor device 200 according to the seventh embodiment, since the recess portion 212a is provided on the inner side of a portion immediately above the outer-side end portion of the p-type region 202 in which the current is likely to be concentrated on the inactive region 212, the concentration of the current is dispersed to the active portion 291 side, and the current is likely to move to the active portion 291 side. In this manner, by providing a significant point of electric field concentration and pulling out a current from the significant point, it is possible to create a carrier path as close as possible to the active portion.

### Eighth Embodiment

In the semiconductor device 200 according to an eighth embodiment, the inactive region 212 has a plurality of recess portions 212a on a lower side. One recess portion 12a is located on the outer side of another recess portions 12a. A magnitude relationship between the dimension of one recess portion 12a in the depth direction and the dimension of another recess portion 12a in the depth direction may be the same as the magnitude relationship between the dimension d2 and the dimension d3 described in the third embodiment and the modification example thereof.

For example, as illustrated in FIG. 11, the inactive region 212 may have the plurality of recess portions 212a. In addition, for example, the inactive region 212 may have both the recess portion 212a illustrated in FIG. 8 and the recess portion 212a illustrated in FIG. 9.

### «Main Effects of Eighth Embodiment»

With the semiconductor device 200 according to the eighth embodiment as well, the same effects as the effects of the semiconductor device 200 according to the fourth embodiment are obtained.

### [Simulation Results]

Hereinafter, simulation results of an electric field strength performed on the well region 12 of the IGBT will be described. In the related art, an electric field tends to be concentrated on an end portion of a guard ring and a well region, more specifically, at a portion having a curvature of a semiconductor region.

A simulation is performed only with the well region 12 and the guard ring 13 excluding the active portion 101. FIGS. 13 and 14 illustrate electric field strengths in the well region 12, the guard ring 13, and the drift layer 3. The well region 12 has the recess portion 12a on a lower side. The recess portion 12a illustrated in FIG. 13 is referred to as a recess portion 12x, and the recess portion 12a illustrated in FIG. 14 is referred to as a recess portion 12Y, and the recess portions 12a may be distinguished from each other. FIGS. 13 and 14 differ in a dimension of the recess portion 12a in a depth direction. More specifically, the dimension of the recess portion 12Y illustrated in FIG. 14 in the depth direction is set to be deeper than the dimension of the recess portion 12X illustrated in FIG. 13 in the depth direction.

From the simulation results illustrated in FIG. 13, it can be seen that a current filament is generated at an outer-side end portion (for example, a curved portion) of the well region 12. In the simulation result illustrated in FIG. 13, the dimension of the recess portion 12X in the depth direction is shallower than the dimension in the simulation result illustrated in FIG. 14. In FIG. 13, it is considered that a distribution of an electric field strength is obtained as when the well region 12 does not have the recess portion since the recess portion is too shallow. On the other hand, in the simulation result illustrated in FIG. 14, it can be seen that the electric field at the outer-side end portion of the well region 12 is relaxed, and a local current is generated at a position closer to the bottom (lower side) of the well region 12. In the simulation result illustrated in FIG. 14, it is considered that the electric field at the outer-side end portion of the well region 12 is relaxed since the recess portion 12Y is provided to be sufficiently deep. In this manner, when the depth of the recess portion 12a is too shallow, the influence of the recess portion 12a on the electric field is too small, and the influence on changing a position at which the electric field is concentrated is too small.

In addition, when the depth of the recess portion 12a is too deep, there is a possibility that the well region 12 is divided into two, resulting a state in which the recess portion 12a is not present. Then, when the well region 12 is divided into two, an equipotential line extends between the divided well regions 12. Then, the electric field may be concentrated on the outer-side end portion of the well region 12 on the inner side in the divided well region.

As a result of the examination, it is found that it is desirable to provide the dimensions d2 and d3 of the recess portion 12a in the depth direction according to the first to third embodiments described above to be a dimension of ⅓ or more and ⅔ or less of the dimension d1 of the well region 12 in the depth direction to suppress the electric field concentration on the outer-side end portion. By providing the depth of the recess portion 12a with an appropriate value, a position at which the recess portion 12a of the well region 12 is provided functions as an end portion, and the electric field is able to be attracted.

In addition, when the active portion 101 is miniaturized for loss improvement, a magnitude relationship between an area of the active portion 101 and an area of the termination region 102 is likely to be affected by manufacturing variations. There is a possibility that a breakdown voltage of the breakdown voltage withstanding structure provided in the termination region 102 may be decreased. On the other hand, by providing the recess portion 12a on the lower side of the well region 12, breakdown voltage performance of the well region 12 is able to be improved without depending on the influence of the manufacturing variation. Therefore, it is possible to suppress the variation in the avalanche breakdown voltage amount due to the manufacturing variation.

The influence of the dimension of the recess portion 12a in the depth direction on the electric field is the same even in a case of the diode. Therefore, it is also desirable that the dimension d2 of the recess portion 12a in the depth direction according to the fourth to eighth embodiments is provided to be a dimension of approximately ⅓ or more and ⅔ or less of the depth d1 of the inactive region 212. Therefore, the same effect as in the case of the IGBT is exhibited.

### Other Embodiments

The first to eighth embodiments of the present disclosure are described. Meanwhile, the description and the drawings forming a part of the disclosure are not intended to limit the present disclosure. From this disclosure, various alternative embodiments, examples, and operational technologies will be apparent to those skilled in the art.

For example, although the IGBT is exemplified as the semiconductor device according to the first to third embodiments described above, the present disclosure can also be applied to a reverse conduction type IGBT (RC-IGBT) or a reverse blocking insulated gate type bipolar transistor (RB-IGBT). In addition, the present disclosure can also be applied to a MOSFET having a configuration in which an n+-type drain region is provided instead of the p+-type collector region 1.

In the first to eighth embodiments, silicon (Si) is used as a material of the semiconductor substrate, but the semiconductor material is not limited, and may be, for example, a wide band gap semiconductor such as silicon carbide (SiC) or gallium nitride (GaN). In addition, the transistor according to the first to third embodiments described above is a trench gate type, but the present disclosure is not limited thereto, and may be a planar type. In addition, the breakdown voltage structures according to the first to eighth embodiments described above do not need to be a guard ring, and a JTE structure, a RESURF structure, a VLD structure, and the like may be used.

In addition, the configurations disclosed in the first to eighth embodiments are able to be appropriately combined without causing contradictions. In this manner, the present disclosure includes various embodiments and the like that are not described here. Therefore, the technical scope of the present disclosure is determined only by the invention specifying matters pertaining to the appropriate claims from the above description.

The planar shape of the gate wiring electrode 16 may be a known shape and is not limited to the shape illustrated in FIG. 1. In addition, the dimension W4 may satisfy a relationship of C × d1≤W4≤20 μm.

1. A semiconductor device comprising:
an active portion;
a termination region surrounding the active portion in a plan view;
a drift layer of a first conductivity type provided over the active portion and the termination region;
a first region of a second conductivity type provided on an upper surface side of the drift layer at the active portion; and
a second region of the second conductivity type provided on the upper surface side of the drift layer at the termination region and surrounding the first region in the plan view,
wherein the second region has a recess portion on a lower side, and
a dimension of the recess portion in a depth direction is ⅓ or more and ⅔ or less of a dimension of the second region in the depth direction.

2. The semiconductor device according to claim 1, further comprising:
a transistor provided at the active portion and having the first region as a base region; and
a gate wiring electrode surrounding the active portion in the plan view and electrically connected to a gate electrode of the transistor,
wherein the second region is a well region, and has an upper surface facing the gate wiring electrode,
a lower surface of the well region is deeper than a lower surface of the first region, and
when an active portion side is defined as an inner side and a termination region side is defined as an outer side, the recess portion is located on the outer side of an inner-side end portion of the gate wiring electrode.

3. The semiconductor device according to claim 2,
wherein the well region and the recess portion are provided in an annular shape along the gate wiring electrode in the plan view.

4. The semiconductor device according to claim 2,
wherein the recess portion is located on the outer side of an outer-side end portion of the gate wiring electrode.

5. The semiconductor device according to claim 4,
wherein along a direction toward the outer side, when a dimension from the inner-side end portion to the outer-side end portion of the gate wiring electrode is defined as W1 and a dimension from a position at which the inner-side end portion of the gate wiring electrode is present to a position at which the recess portion is present is defined as W2, a dimension of the well region in the depth direction is defined as d1, and a constant C is a value of 0.75 or more and 0.85 or less, a relationship of W2≥W1+C×d1 is satisfied.

6. The semiconductor device according to claim 1,
wherein a field plate electrically connected to the second region is provided in a region on the outer side of the recess portion of the second region.

7. The semiconductor device according to claim 2,
wherein the recess portion is located on the inner side of an outer-side end portion of the gate wiring electrode.

8. The semiconductor device according to claim 2,
wherein the well region has a plurality of the recess portions.

9. The semiconductor device according to claim 8,
wherein the well region has a first recess portion located on the outer side of an outer-side end portion of the gate wiring electrode and a second recess portion located on the inner side of the outer-side end portion of the gate wiring electrode, as the recess portion.

10. The semiconductor device according to claim 9,
wherein a dimension of the second recess portion in the depth direction is larger than a dimension of the first recess portion in the depth direction.

11. The semiconductor device according to claim 2, further comprising:
a breakdown voltage structure of the second conductivity type provided on the upper surface side of the drift layer and located on the outer side of the well region.

12. The semiconductor device according to claim 11,
wherein the breakdown voltage structure is a guard ring.

13. The semiconductor device according to claim 2,
wherein the well region overlaps with the entire gate wiring electrode in the plan view.

14. The semiconductor device according to claim 2, further comprising:
a main electrode in contact with an upper surface of a main region of the transistor,
wherein the well region is electrically connected to the main electrode.

15. The semiconductor device according to claim 2,
wherein the gate electrode of the transistor is of a trench gate type.

16. The semiconductor device according to claim 1, further comprising:
a diode having the first region as a main region,
wherein the second region is an inactive region, and an inner-side end portion of the second region is in contact with an outer-side end portion of the first region, and
the second region is formed continuously and integrally with the first region, and the dimension of the second region in the depth direction is provided to be the same as a dimension of the first region in the depth direction.

17. The semiconductor device according to claim 16, further comprising:
a third region of the first conductivity type serving as a main region and provided on a lower surface side of the drift layer.

18. The semiconductor device according to claim 17,
wherein when an active portion side is defined as an inner side and a termination region side is defined as an outer side, an outer-side end portion of the third region is located on the inner side of an outer-side end portion of the drift layer, and
the recess portion is located on the inner side of the outer-side end portion of the third region.

19. The semiconductor device according to claim 17,
wherein when an active portion side is defined as an inner side and a termination region side is defined as an outer side, an outer-side end portion of the third region is located on the inner side of an outer-side end portion of the drift layer, and
the recess portion is located on the outer side of the outer-side end portion of the third region.

20. The semiconductor device according to claim 19,
wherein along a direction toward the outer side, when a dimension in a lateral direction from a position at which the outer-side end portion of the third region is present to a position at which the recess portion is present is defined as W4, the dimension of the second region in the depth direction is defined as d1, and a constant C is a value of 0.75 or more and 0.85 or less, a relationship of C×d1<W4<20 μm is satisfied.

21. The semiconductor device according to claim 17, further comprising:
a fourth region of the second conductivity type provided on an upper surface side of the third region,
wherein an outer-side end portion of the fourth region is located on the inner side of an outer-side end portion of the second region, and
the recess portion is located on the inner side of the outer-side end portion of the fourth region.

22. The semiconductor device according to claim 16,
wherein the second region has a plurality of the recess portions.

23. The semiconductor device according to claim 16,
wherein the recess portion is provided in an annular shape along the second region in the plan view.
